(19) United States
(12) Patent Application Publication
(10) Pub. No.: US 2003/0198542 A1
(43) Pub. Date: Oct. 23, 2003

(54) Cassette pod stage equipped with locked guide pins

(75) Inventors: Chih-Pen Yen, Kaohsiung (TW); Jenq-Yann Tsay, Tainan (TW); Ta-Chin Lee, Taichung (TW); Jeng-Chiang Chuang, Kaohsiung (TW); Yung-Mao Hsu, Tainan (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/127,088

(22) Filed: Apr. 22, 2002

(51) Int. Cl. B65G 69/00; H01L 21/00

(52) U.S. Cl. 414/217.1; 118/719; 414/740

(57) ABSTRACT

A cassette pod stage that is equipped with locked guide pins is described. The cassette pod stage of the present invention is provided with at least one aperture therethrough for engaging at least one guide pin. The guide pin is provided with a top portion, a bottom portion and a skirt portion in-between the top portion and the bottom portion for use as a stop during installation of the guide pin through an aperture in the cassette pod stage. The bottom portion of the guide pin is provided with a threaded portion for engaging a locking nut after the guide pin is installed with the threaded portion extending beyond the bottom surface of the cassette pod stage for such engagement.

### FIELD OF THE INVENTION

The present invention generally relates to a cassette pod stage of a loadport of a semiconductor process machine and more particularly, relates to a cassette pod stage of a loadport that is equipped with guide pins that are locked to the stage.

### BACKGROUND OF THE INVENTION

In the manufacturing of a semiconductor device, the device is usually processed at many work stations or processing machines. The transporting or conveying of partially finished devices, or work-in-process (WIP) parts, is an important aspect in the total manufacturing process. The conveying of semiconductor wafers is especially important in the manufacturing of integrated circuit chips due to the delicate nature of the chips. Furthermore, in fabricating an IC product, a multiplicity of fabrication steps, i.e., as many as several hundred, is usually required to complete the fabrication process. A semiconductor wafer or IC chips must be transported between various process stations in order to perform various fabrication processes.

For instance, to complete the fabrication of an IC chip, various steps of deposition, cleaning, ion implantation, etching and passivation steps must be carried out before an IC chip is packaged for shipment. Each of these fabrication steps must be performed in a different process machine, i.e. a chemical vapor deposition chamber, an ion implantation chamber, an etcher, etc. A partially processed semiconductor wafer must be conveyed between various work stations many times before the fabrication process is completed. The safe conveying and accurate tracking of such semiconductor wafers or work-in-process parts in a semiconductor fabrication facility is therefore an important aspect of the total fabrication process.

Conventionally, partially finished semiconductor wafers or WIP parts are conveyed in a fabrication plant by automatically guided vehicles or overhead transport vehicles that travel on predetermined routes or tracks. For the conveying of semiconductor wafers, the wafers are normally loaded into cassettes pods, such as SMIF (standard machine interface) or FOUP (front opening unified pod), and then picked up and placed in the automatic conveying vehicles. For identifying and locating the various semiconductor wafers or WIP parts being transported, the cassettes or pods are normally labeled with a tag positioned on the side of the cassette or pod. The tags can be read automatically by a tag reader that is mounted on the guard rails of the conveying vehicle.

In modern semiconductor fabrication facilities, especially for the 200 mm or 300 mm FAB plants, automatic guided vehicles (AGV) and overhead hoist transport (OHT) are extensively used to automate the wafer transport process as much as possible. The AGE and OHT utilize the input/output ports of a stocker to load or unload wafer lots, i.e. normally stored in POUFs. The OHT system is also used to deliver a cassette pod such as a FOUP to a process machine. This is shown in FIG. 1. A cassette pod 10 of the FOUP type is positioned on a loadport 12 of a process machine 14. The loadport 12 is frequently equipped with a plurality of locating pins 16 for the proper positioning of the cassette pod 10. A detailed perspective view of the FOUP 10 is shown in FIG. 2. The FOUP 10 is constructed of a body portion 18 and a cover portion 28. The body portion 18 is provided with a cavity 46 equipped with a multiplicity of partitions 48 for the positioning of 25 wafers of the 300 mm size. The body portion 18 is further provided with sloped handles 50 on both sides of the body for ease of transporting. On top of the body portion 18, is provided with a plate member 52 for gripping by a transport arm (not shown) of an OHT system (not shown).

When an OHT system is utilized in transporting a cassette pod to a process machine, problems arise when the loadport of the process machine is not in alignment with the OHT system. Mis-positioned cassette pods on a loadport not only affects the operation of loading/unloading wafers from the pod, but also in severely misaligned instances may cause the cassette pod to tip over resulting in the breakage of wafers. Conventionally, a plurality of guide pins, i.e. at least three guide pins, are utilized on top of a cassette pod stage for guiding the mounting and positioning of the cassette pod. This is shown in FIGS. 3, 3A and 4.

FIG. 3 is a side view of a loadport 12 of a process machine 14. The loadport 12 is equipped with a cassette pod stage 20 provided with at least three apertures 22 for engaging at least three guide pins 16. The guide pins 16 are used for guiding the positioning of the cassette pod 10 onto the cassette pod stage 20. An enlarged view of the engagement between the cassette pin 16 and the aperture 22 is shown in FIG. 3A, while an enlarged view of the guide pin 16 is shown in FIG. 6A.

The conventional guide pin 16 is fabricated of a steel shaft with a uniform diameter except that the tip portion 24 is rounded and tapered for easier engagement with apertures located on the bottom panel 26 of a cassette pod 10. The conventional guide pin 16 engages the aperture 22 provided in the cassette pod stage 20 by frictional engagement which is achieved by machining the outer diameter of the guide pin 16 to slightly smaller, i.e., about 0.5 mm smaller than approximately the same as the inside diameter of the aperture 22. The guide pin 16 is pressed into the aperture 22 by a mechanical force such as by the force of a platen in a press. After repeated usage, the guide pin 16 may be further pressed into the aperture 22 and thus, the height of the exposed portion of the guide pin shaft may be reduced. In extreme circumstances, the guide pin 16 may even be pushed into the aperture 22 completely and thus, no longer serves its function for guiding the positioning of a cassette pod on top of the stage.

In the conventional setup of the guide pin 16, the guide pin 16 may also be distorted after repeated usage, i.e. may be slightly bent from its original vertical position. When such condition exists, the mounting of a cassette pod onto the guide pins 16 would be difficult. Furthermore, when the cassette pod is removed from the cassette pod stage, the excessively large frictional force between the aperture 58 located in the bottom panel of the cassette pod and the guide pin 16 may be such that the guide pin may be pulled up from its inserted position. A dis-positioned guide pin 16 can thus cause other positioning problems for the cassette pod. The mis-alignment of the guide pins 16 with the aperture 58 located in the bottom panel 26 of the cassette pod 10 may cause serious processing difficulties for the loading or unloading of a cassette pod.

It is therefore an object of the present invention to provide a cassette pod stage equipped with guide pins that do not have the drawbacks or shortcomings of the conventional pod stage.

It is another object of the present invention to provide a cassette pod stage that is equipped with guide pins that are equipped with a skirt portion for preventing further insertion of the guide pin into a mounting aperture.

It is a further object of the present invention to provide a cassette pod stage that is equipped with guide pins which are locked onto the stage.

It is another further object of the present invention to provide a cassette pod stage that is equipped with guide pins that are locked onto the stage and cannot be pulled out even with excessive frictional force between the guide pins and the cassette pod.

It is still another object of the present invention to provide a cassette pod stage that is equipped with guide pins which are locked onto the stage by a locking nut.

### SUMMARY OF THE INVENTION

In accordance with the present invention, a cassette pod stage that is equipped with locked guide pins in the top surface of the stage is provided.

In a preferred embodiment, a cassette pod stage that is equipped with locked guide pins is provided including a cassette pod stage that has a top surface and a bottom surface defining a first thickness therein-between, the cassette pod stage has at least one aperture therethrough, the aperture has a first diameter; at least one guide pin engaging the at least one aperture, the at least one guide pin further includes a top portion and a bottom portion with a skirt portion therein-between; the top portion has a smooth, tapered top and a second diameter larger than a third diameter of the bottom portion, the third diameter of the bottom portion is smaller than the first diameter of the aperture, the skirt portion has a fourth diameter larger than the first diameter of the aperture; the bottom portion has a length larger than the first thickness of the cassette pod stage and is provided at least partially with a thread for engaging a locking nut; and at least one locking nut for threadingly engaging the thread on the bottom portion of the at least one guide pin.

In the cassette pod stage that is equipped with locked guide pins, the skirt portion has a planar bottom surface for engaging the top surface of the cassette pod stage and for acting as a stop during installation of the at least one guide pin into the at least one aperture through the cassette pod stage. The fourth diameter of the skirt portion is at least 2 mm larger than the first diameter of the aperture. The third diameter of the bottom portion is at least 1 mm smaller than the first diameter of the aperture. The threaded region of the bottom portion extends to a bottom end of the at least one guide pin.

In the cassette pod stage equipped with locked guide pins, the threaded region of the bottom portion extends beyond the bottom surface of the cassette pod stage by at least 5 mm when the at least one guide pin is installed through the at least one aperture, or the threaded region of the bottom portion extends beyond the bottom surface of the cassette pod stage preferably by at least 8 mm when the at least one guide pin is installed through the at least one aperture. The cassette pod stage is a loadport stage for a semiconductor process equipment. The at least one guide pin may be three guide pins. The at least one aperture in the stage may be three apertures. The cassette pod stage receives a cassette pod that holds 200 mm wafers. The third diameter of the bottom portion of the at least one guide pin is at least 1 mm smaller, but not more than 3 mm smaller than the first diameter of the aperture.

### BRIEF DESCRIPTION OF THE DRAWINGS

These and other objects, features and advantages of the present invention will become apparent from the following detailed description and the appended drawings in which:

FIG. 1 is a perspective view of a conventional cassette pod positioned on a loadport.

FIG. 2 is a perspective view of a cassette pod and a cassette pod door for 300 mm diameter wafers.

FIG. 3 is a side view of a loadport of a process machine with a cassette pod mounted on top.

FIG. 3A is a partial, enlarged view of the engagement between a guide pin, an aperture in a cassette pod stage and an aperture in a bottom panel of a cassette pod.

FIG. 4 is a plane view of a loadport with conventional guide pins installed in a top surface.

FIG. 5 is a partial, enlarged view of the present invention locking guide pin installed in an aperture of a cassette pod stage engaging an aperture in a bottom panel of a cassette pod.

FIG. 6 is an enlarged, cross-sectional view of a locking guide pin of the present invention.

FIG. 6A is an enlarged, cross-sectional view of the conventional guide pin for the cassette pod stage.

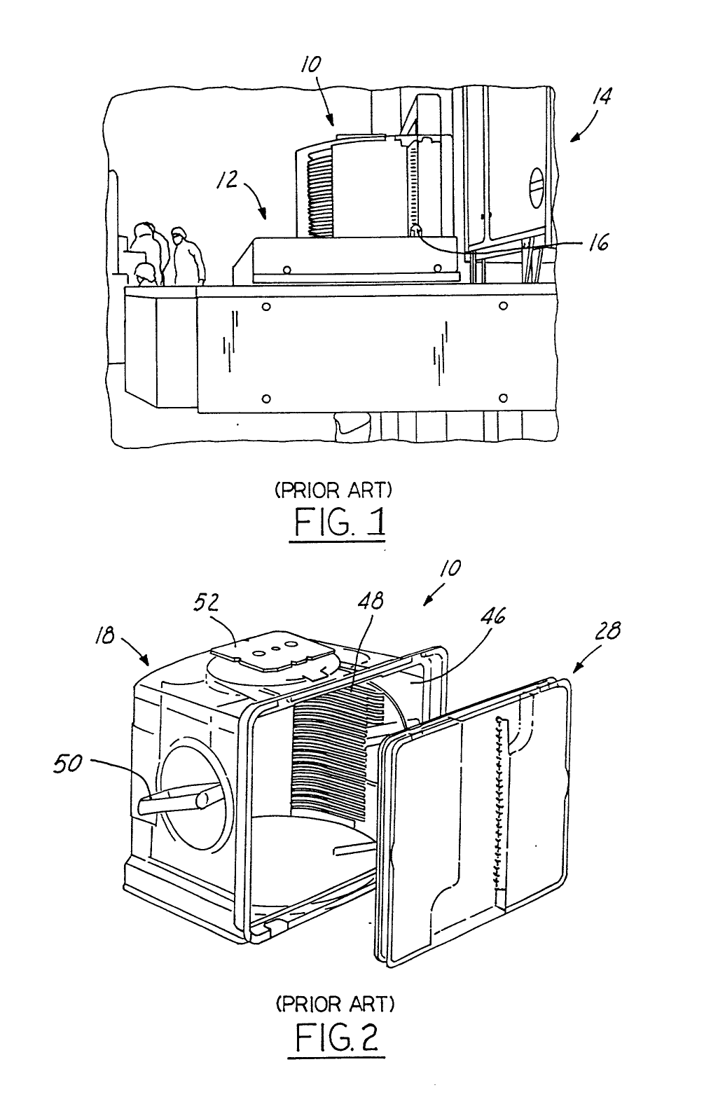

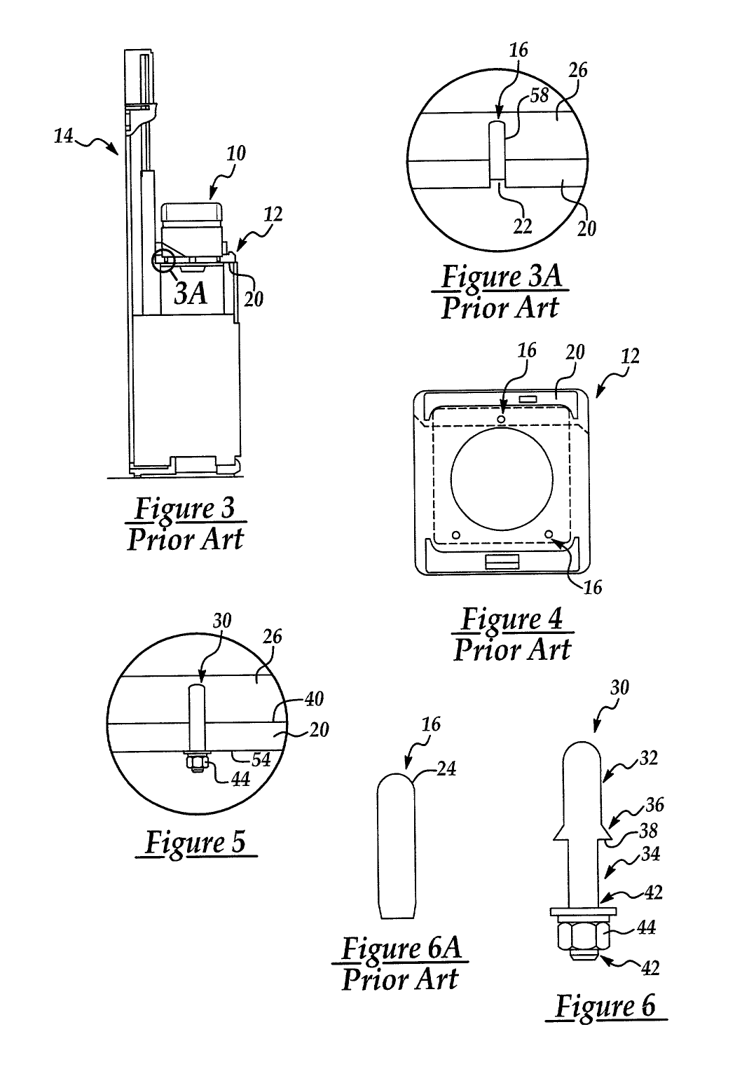

### DETAILED DESCRIPTION OF THE PREFERRED EMBODIMENT

The present invention discloses a cassette pod stage that is equipped with locked guide pins for engaging or guiding the positioning of a cassette pod onto a loadport.

The cassette pod stage of the present invention includes a cassette pod stage that is provided with at least one aperture therethrough, at least one guide pin engaging the at least one aperture in the stage, and at least one locking nut for engaging a threaded portion of the guide pin and for locking the guide pin onto the cassette pod stage.

The present invention guide pin has a top portion of a larger diameter and a bottom portion of a smaller diameter. The smaller diameter of the bottom portion enables it to go through an aperture in the cassette pod stage during installation of the guide pin. The bottom portion of the guide pin is further provided with a threaded portion such that, when the bottom portion extends beyond the cassette pod stage, it can be threadingly engaged by a locking nut and thereby locked onto the stage. The locking arrangement of the guide pin ensures that the guide pin, even when excessive frictional force exists between the guide pin and an apertures at the bottom of the cassette pod, cannot be pulled out during a removal process of a cassette pod from the cassette pod stage.

The threaded portion of the bottom portion of the guide pin should extend beyond the bottom surface of the cassette pod stage by at least 5 mm, and preferably by at least 8 mm for threadingly engaging a locking nut.

For a SMIF pod used for holding 200 mm diameter wafers, or for a POUF that is used for holding 300 mm diameter wafers, at least 3 guide pins are desirable for the cassette pod stage in order to guide properly a cassette pod onto the stage of the loadport. The present invention novel cassette pod stage that is equipped with locking guide pins can be used for any loadport, regardless of the cassette pod size.

Referring now to FIGS. 5 and 6, wherein FIG. 6 shows an enlarged, cross-sectional view of a present invention guide pin 30 and FIG. 5 shows an enlarged, partial view of an engagement between the guide pin 30, a cassette pod stage 20 and a bottom panel 26 of a cassette pod. The locking guide pin 30, shown in FIG. 6, is constructed of a top portion 32 and a bottom portion 34 with a skirt portion 36 therein between. The skirt portion 36 is further provided with a planar bottom surface 38 for engaging, as a stop, a top surface 40 of the cassette pod stage 20.

FIG. 6 further shows that the bottom portion 34 of the locking guide pin 30 is further provided with a threaded portion 42 for engaging a locking nut 44. The length of the bottom portion 34 should be longer, i.e. by at least 5 mm than the thickness of the cassette pod stage 20 such that the threaded portion 42 extends beyond the bottom surface 54 of the cassette pod stage 20 to facilitate the engagement of the locking nut 44. Preferably, the bottom portion 34 of the locking guide pin 30 should extend beyond the bottom surface 54 by at least 8 mm, and more preferably by at least 1 cm to facilitate such engagement. After the locking nut 34 is engaged on the threaded portion 42 of the locking guide pin 30 on a cassette pod stage 20, the guide pin 30 cannot be pulled out even with excessive frictional force exists between the top portion 32 and the aperture 58 in the bottom panel 26 of the cassette pod 10.

As shown in FIG. 6, the skirt portion 36 of the locking guide pin 30 should have an outer diameter that is at least 2 mm larger than the diameter of the aperture 22 such that the skirt portion 36 acts as a stop during the installation of the guide pin 30. The skirt portion 36 provides the additional benefit of the present invention locking guide pin in that, regardless of any successive pounding on the guide pin 30 during usage, the height of the top portion 32 above the top surface 40 of the cassette pod stage 20 remains the same and cannot be pushed further into the aperture 22. The present invention locking guide pin 30, after installed into a cassette pod stage, can therefore securely stay in place without the danger of being further pushed in or being pulled out.

The present invention cassette pod stage that is equipped with locked guide pins have therefore been amply described in the above description and in the appended drawings of FIGS. 5 and 6.

While the present invention has been described in an illustrative manner, it should be understood that the terminology used is intended to be in a nature of words of description rather than of limitation.

Furthermore, while the present invention has been described in terms of a preferred embodiment, it is to be appreciated that those skilled in the art will readily apply these teachings to other possible variations of the inventions.

The embodiment of the invention in which an exclusive property or privilege is claimed are defined as follows.

What is claimed is:

1. A cassette pod stage equipped with locked guide pins comprising:
a cassette pod stage having a top surface, a bottom surface defining a first thickness therein-between, said cassette pod stage having at least one aperture therethrough, said aperture having a first diameter;
at least one guide pin engaging said at least one aperture, said at least one guide pin further comprises:
a top portion and a bottom portion with a skirt portion therein between; said top portion having a smooth, tapered top and a second diameter larger than a third diameter of said bottom portion, said third diameter of the bottom portion being smaller than said first diameter of said aperture, said skirt portion having a fourth diameter larger than said first diameter of said aperture;
said bottom portion having a length larger than said first thickness of the cassette pod stage and is provided at least partially with a thread for engaging a locking nut; and
at least one locking nut for threadingly engaging said thread on said bottom portion of said at least one guide pin.

2. A cassette pod stage equipped with locked guide pins according to claim 1, wherein said skirt portion having a planar bottom surface for engaging said top surface of the cassette pod stage and for acting as a stop during installation of said at least one guide pin into said at least one aperture through said cassette pod stage.

3. A cassette pod stage equipped with locked guide pins according to claim 1, wherein said fourth diameter of the skirt portion is at least 2 mm larger than said first diameter of said aperture.

4. A cassette pod stage equipped with locked guide pins according to claim 1, wherein said third diameter of said bottom portion is at least 0.5 mm smaller than said first diameter of said aperture.

5. A cassette pod stage equipped with locked guide pins according to claim 1, wherein said threaded region of said bottom portion extends to a bottom end of said at least one guide pin.

6. A cassette pod stage equipped with locked guide pins according to claim 1, wherein said threaded region of said bottom portion extends beyond said bottom surface of the cassette pod stage by at least 5 mm when said at least one guide pin is installed through said at least one aperture.

7. A cassette pod stage equipped with locked guide pins according to claim 1, wherein said threaded region of said bottom portion extends beyond said bottom surface of the cassette pod stage preferably by at least 8 mm when said at least one guide pin is installed through said at least one aperture.

8. A cassette pod stage equipped with locked guide pins according to claim 1, wherein said cassette pod stage is a loadport stage for a semiconductor process equipment.

9. A cassette pod stage equipped with locked guide pins according to claim 1, wherein said at least one guide pin is three guide pins.

10. A cassette pod stage equipped with locked guide pins according to claim 1, wherein said at least one aperture in said stage is three apertures.

11. A cassette pod stage equipped with locked guide pins according to claim 1, wherein said cassette pod stage receives a cassette pod holding 200 mm wafers.

12. A cassette pod stage equipped with locked guide pins according to claim 1, wherein said third diameter of said bottom portion of the at least one guide pin is at least 0.5 mm smaller but not more than 3 mm smaller than said first diameter of said aperture.
